(19) United States
(12) Patent Application Publication
(10) Pub. No.: US 2023/0213375 A1
(43) Pub. Date: Jul. 6, 2023

(54) VIBRO-ELECTRIC CONDITION MONITORING

(71) Applicant: UNIVERSITY OF SALFORD ENTERPRISES LIMITED, Salford (GB)

(72) Inventor: Andrew Stephen ELLIOTT, Manchester (GB)

(73) Assignee: UNIVERSITY OF SALFORD ENTERPRISES LIMITED, Salford (GB)

(21) Appl. No.: 17/793,320

(22) PCT Filed: Jan. 18, 2021
(86) PCT No.: PCT/GB2021/050110

§ 371 Date: Jul. 15, 2022

(30) Foreign Application Priority Data
Jan. 17, 2020 (GB) 2000742.3

(51) Int. Cl. G01H 1/00; G01M 7/02; G01M 13/045

(52) U.S. Cl. CPC G01H 1/003; G01M 7/02; G01M 13/045; G01R 31/343

(57) ABSTRACT

Apparatus (10) for monitoring the condition of an item of electrical equipment (1) whilst in operation comprises a vibration sensor (11) and an electrical sensor (12) operable to detect a characteristic operational electrical signal of the equipment (1). The output of the vibration sensor (11) and the electrical sensor (12) is supplied to a spectrum generator (13) and then to a processing unit (14) operable to process the respective frequency spectrums to generate a frequency response function. Once a frequency response function is generated, the processing unit (14) is operable to compare the generated frequency response function to a model frequency response function. This allows any variations between the generated frequency response function and the model frequency response function to be identified. This could be indicative of a fault and could provide an identification of the nature of the fault.

### TECHNICAL FIELD OF THE INVENTION

The present invention relates to a method and apparatus for monitoring the condition of electrical equipment in operation. In particular, the present invention relates to a method and apparatus for monitoring the condition of electrical equipment by sensing vibrations produced by said equipment in operation. More particularly, the present invention relates to a method and apparatus for monitoring the condition of electrical equipment operable to generate or act on rotary motion, when in operation.

### BACKGROUND TO THE INVENTION

At the present time, a significant fraction of electrical energy worldwide is produced by or consumed by electrical equipment or machinery linked to electrical equipment. In particular this includes equipment incorporating rotary elements such as generators, motors and the like. Improving the efficiency of such equipment or the efficiency of the performance of the equipment and any linked machinery can significantly improve the overall energy efficiency of any home, business or supply grid. One way to improve such energy efficiency is to improve the design of such equipment however, this only improves the performance of new equipment.

To optimise the performance of older equipment it is necessary to maintain the equipment appropriately. This may involve regular servicing. Additionally, ad hoc maintenance may be required on other occasions. In general, this requires monitoring the condition of the equipment by use of suitable sensors. One example would be vibration monitoring which senses vibration of the equipment. In the event that the magnitude or frequency of the vibration falls outside an expected range, this can provide an indication that the performance of the equipment is not optimal. Accordingly, ad hoc maintenance can be initiated.

Whilst such an approach can be useful, it can be inaccurate. In particular, this can occur when the equipment may have a wide range of different vibration levels in normal operation. For instance, an electric motor may operate under a wide range of speed/load combinations and each speed/load combination may have a different vibrational profile. In such cases, it is difficult to select an expected vibration range that includes only levels of vibration indicative of normal operation and excludes only levels of vibration indicative of a fault.

In relation to transformers, documents such as WO2010/060253 and CN109697437 teach that the state of transformer windings might be assessed by exciting the windings with a constant current sweep frequency power source and measuring the resultant vibrational response. This provides a measure of winding state under various different frequency excitations. By analysing the vibration frequency response, it is possible to identify resonant frequencies of the windings which can provide an indication as to the state of the transformer. such techniques are difficult to apply more widely than to transformers and suffer from the significant disadvantage that the equipment must be taken offline to allow for analysis. Additionally, the need to use a constant current sweep frequency power source as an input may not accurately replicate operating conditions.

It is therefore an object of the present invention to provide a method and apparatus for monitoring the condition of electrical equipment in operation that at least partially overcomes or alleviates the above problems.

### SUMMARY OF THE INVENTION

According to a first aspect of the invention there is provided a method for monitoring the condition of electrical equipment in operation, the method comprising the steps of: detecting vibration of the equipment; obtaining a frequency spectrum of the detected vibration; detecting a characteristic operational electrical signal of the equipment; obtaining a frequency spectrum of the detected characteristic operational electrical signal; processing the respective frequency spectrums to generate a frequency response function and comparing the generated frequency response function to a model frequency response function so as to identify any variations between the generated frequency response function and the model frequency response function.

According to a second aspect of the present invention there is provided an apparatus for monitoring the condition of electrical equipment in operation, the apparatus comprising: a vibration sensor operable to detect vibration of the equipment and output a signal indicative thereof; an electrical sensor operable to detect a characteristic operational electrical signal of the equipment and to output a signal indicative thereof; a spectrum generator operable to receive the output of the vibration sensor and electrical input sensor and to thereby generate a frequency spectrum of the detected vibration and a frequency spectrum of the detected characteristic operational electrical signal; and a processing unit operable to process the respective frequency spectrums to generate a frequency response function and to compare the generated frequency response function to a model frequency response function so as to identify any variations between the generated frequency response function and the model frequency response function and output an indication thereof.

The above method and apparatus thereby enable performance of electrical equipment to be monitored in a manner that can take account of variation in expected vibration over the full operating range of the equipment and can be used during operation of the equipment. In particular, the use of the frequency response function allows for improved analysis across a wide range of operating conditions. Use of the characteristic operational electrical signal rather than a test signal enables a more accurate monitoring of equipment condition.

The characteristic operational electrical signal may be any electrical signal that occurs during operation of the equipment. This ensures that monitoring can take place in operation rather than requiring the equipment to be taken off-line for the application of a test signal. In the case of power consuming equipment, the characteristic operational electrical signal may be an input electrical signal. This may even be applied to DC input signals. For instance, if a DC signal is input to an electrical motor, variation in motor speed and load can generate a measurable ripple on the input DC signal. In the case of power generating equipment, the characteristic operational electrical signal may be an output electrical signal. In passive electrical equipment, the characteristic operational electrical signal may be measured at a suitable node. In this context, passive electrical equipment may include electrical transmission networks, transformers and the like.

In some embodiments, the method may involve detection of more than one characteristic operational electrical signal. This can be achieved by use of multiple characteristic operational electrical signal sensors. The detection of multiple characteristic signals may be utilised where the equipment contains multiple different components. This can allow closer monitoring of said components within the equipment.

Detection of the characteristic signal may include detection of any attribute of the characteristic operational electrical signal. Suitable attributes may include, but are not limited to: current, voltage or power. In embodiments where more than one attribute of the characteristic operational electrical signal is measured, the method may include generation of separate frequency response functions for each attribute and comparison of the separate generated frequency response functions for these attributes.

In some embodiments, the method may involve detection of vibration of the equipment at a single point. This can be achieved using a single vibration sensor. In other embodiments, the method may involve detection of vibration of the equipment at multiple points. This can be achieved using multiple vibration sensors. Where there are multiple vibration sensors, they may be spaced apart from one another around the equipment. This can help to monitor the operation of different components within the equipment.

In some embodiments, vibrations may be detected using a single type of vibration sensor. In other embodiments, vibrations may be detected using different types of vibration sensor. In some embodiments, this may include providing multiple vibration sensors at each vibration sensing point. In other embodiments, this may include using different types of vibration sensor at different vibration sensing points. This can improve detection of vibrations across a full range of expected vibrations. This can also enable vibration of particular components to be detected using particularly suitable types of vibration sensors.

In embodiments utilising multiple vibration sensors, the method may include the steps of generating separate frequency response functions for each vibration sensor.

Suitable types of vibration sensor include but are not limited to: accelerometers, piezoelectric sensors, pressure sensor, Hall effect sensors, microphones, optical fibre gratings, strain gauges and the like.

The method may include the step of calculating the auto spectrum of detected vibration and characteristic operational electrical signals. The method may include the step of calculating the cross spectrum of detected vibration and characteristic operational electrical signals. The calculation of the auto spectrum and/or cross spectrum may be carried out by the spectrum generator. The calculation may be achieved by use of a fast Fourier transform (FFT) technique.

The method may include the step of further monitoring or analysing the calculated auto and cross spectra. This further monitoring or analysis may be carried out by the processing unit.

In some such embodiments, the method may include the step of calculating the coherence of the detected vibration and/or characteristic operational electrical signals. The coherence γ may be calculated from a function of the type:

$${γ}^{2} = \frac{{\vert {G}_{A B} \vert}^{2}}{{G}_{A} \cdot {G}_{B}}$$

wherein G_{A} is the auto spectrum of channel A, G_{B} is the auto spectrum of channel B, and G_{AB} is the cross spectrum of channels A and B. In such embodiments, the method may involve the step of monitoring the coherence value over time. In this context, a change in the coherence value over time may indicate the development of a fault. For instance, where the coherence is equal to 1, there is a constant relationship between input and output whereas if the coherence drops to less than 1, then the relationship between input and output has changed.

In the event that multiple signals are detected, the calculation of coherence between any or all of the characteristic operational electrical signals and/or the vibration signal may be calculated. In particular, this may be calculated from a combined coherence function of the type:

$${γ}_{A i : B}^{2} = {\sum }_{i}^{m} {γ}_{{A}_{i}^{′} : B}^{2}$$

wherein m is the number of incoherent inputs and γ_{Ai:B} is the coherence for each individual signal.

In the event that multiple signals are detected, the method may include conducting an operational transfer path analysis using the auto spectrum and cross spectrums of the signals. Such an analysis can be used to generate a transmissibility matrix indicative of the relationship between input and output. In such embodiments, the method may involve the step of monitoring the transmissibility matrix over time. In this context, a change in the transmissibility matrix over time may indicate the development of a fault. The method may further include the step of analysing the change in the transmissibility matrix so as to identify the likely origin of the fault.

In the event that multiple signals are detected, the method may include conducting a principal component analysis. In such embodiments, the method may involve the step of monitoring the principal component analysis over time. In such embodiments, a fault may be identified by a change in one of the principal component axes.

The method may include generating a force frequency response function from the vibration frequency response function. The method may involve comparing the generated force frequency response function to a model force frequency response function. This can facilitate the identifications of variations between the generated force frequency response function and the model frequency response function and hence the identification of potential faults.

Determination of the force frequency response function from the measured vibration frequency response function may be achieved by inverse methods. In particular, this may involve determination of the operational force or blocked force. The blocked force can be understood as the amount of force required to counter the vibratory motion of the equipment (i.e. such that velocity, displacement and acceleration of the equipment is zero). This can be measured using a force transducer terminated by an infinitely massive and stiff object. Since this is generally not practical it may also be obtained using inverse methods. Using this approach the force can be determined providing a frequency response function such as the accelerance of the equipment is known. The accelerance may be predefined or may be measured. The accelerance is preferably measured at the location of the vibration sensor.

The accelerance may be defined as the structural frequency response function of the equipment. As such, the accordance describes the acceleration of the equipment structure due to a unit force input. More specifically, the accelerance A may be defined as:

$$A = \frac{a}{F}$$

Where a is the acceleration at the measurement point and F is a unit force input when the equipment is not operating. The accelerance thereby describes passive structural properties of the equipment. As such, the accelerance can be used to remove the influence of resonances from the model frequency response function. Analysis of the force frequency response function against a model force frequency response may then make identification of faults generally or classification of specific faults simpler.

Where the accelerance A is known and the operational acceleration \dot{a} is measured by the vibration sensor, the blocked force f_{bl} may be calculated from

f_{bl}=A⁻¹\dot{a}

The method may include the step of classifying the operation of the equipment in response to any identified variations between the generated frequency response function and the model frequency response function or any identified variations in the calculated auto and/or cross spectra. In such cases, the method may include the analysis of any identified variations to determine whether a fault has occurred and/or the identity of the fault. In such cases, faults may be determined to have occurred or be identified by variations between the generated frequency response function and the model frequency response function that exceed a pre-set threshold or that occur in a particular frequency region. In some embodiments, the method may include the further step of outputting a signal indicative of the fault. In some such embodiments, the method may include the step of generating a maintenance notification including an indication of the identified fault.

In some embodiments, the method may include the further step of outputting a command signal to shut down all or part of the equipment. In such embodiments, the method may include the additional step of shutting down all or part of the equipment. This automatic shutdown of potentially faulty or dangerous equipment can potentially prevent damage or danger being presented by continued operation of the equipment.

The model frequency response function may be generated by modelling the expected frequency response of the equipment. Alternatively, the model frequency response function may be generated by way of a calibration process.

Where multiple vibrations, multiple characteristic operational electrical signals or multiple attributes of the or each characteristic operational electrical signal are detected model frequency response functions may be stored for each vibration, characteristic operational electrical signal or characteristic operational electrical signal attribute.

The calibration process may involve operating the equipment over the full expected range of characteristic operational electrical signals; detecting vibration of the equipment; obtaining a frequency spectrum of the detected vibration; detecting a characteristic operational electrical signal of the equipment; obtaining a frequency spectrum of the detected characteristic operational electrical signal; and processing the respective frequency spectrums to generate a model frequency response function. The calibration process may be carried out at the completion of manufacture of the equipment or on installation of the equipment. In other instances, the calibration process may be undertaken periodically and/or after servicing. Where an item of electrical equipment is mass produced, the calibration process may be undertaken for one or more prototypes of the item of electrical equipment to generate a model frequency response function for subsequently manufactured items of the same type. In further embodiments, the subsequently manufactured items may be subject to a testing process to determine if the frequency response function of each specific item is a sufficiently close match to the model frequency response function.

The or each model frequency response function may be stored in a data store. The data store may be incorporated into or in communication with the processing unit.

The calibration process may include measuring the accelerance. The measured accelerence may be stored for use in determination of excitation forces.

The method may include the step of converting signals from the frequency domain to the time domain. The conversion to the time domain may take place after identifying any variations between the generated frequency response function and the model frequency response function. The time domain signals may be subject to analysis by any suitable time domain analysis including but not limited to kurtosis, variance, skewness or rms level.

The method may include monitoring multiple items of electrical equipment. In some examples, the multiple items may be monitored using one or more common vibration sensors. In such instances, individual characteristic operational electrical signals may be monitored for each item. The electrical equipment may comprise multiple linked items of electrical equipment. In this manner, potential faults can be identified in one item before they can cause damage to linked items. In one example, the multiple linked items of electrical equipment may be provided in the same factory or in a particular production area within a factory.

The method may include monitoring machinery linked to electrical equipment. The linked machinery may comprise machinery powered by the electrical equipment or machinery operable to drive the electrical equipment. This may be achieved by locating one or more vibration sensors on or in the vicinity of such machinery. In this manner, faults with the machinery as a whole and/or faults with the machinery that may impact on the electrical equipment can be monitored.

The electrical equipment may be electrical equipment incorporating rotary elements. The electrical equipment may comprise an electric motor or an electric generator. The electrical equipment may comprise an output device such as a light, display or the like. The electrical equipment may be an electrical detector or the like. The electrical equipment may further incorporate additional components driven by or driving the electrical equipment such as gearing mechanisms, drive mechanisms or the like.

According to a third aspect of the present invention there is provided an item of electrical equipment monitored according to the method of the first aspect of the present invention or comprising an apparatus according to the second aspect of the present invention.

According to a fourth aspect of the present invention there is provided a system comprising a plurality of items item of electrical equipment according to the third aspect of the present invention.

The electrical equipment of the third or fourth aspects of the invention may incorporate any or all of the features of the first two aspects of the present invention as are desired or as appropriate.

### DETAILED DESCRIPTION OF THE INVENTION

In order that the invention may be more clearly understood one or more embodiments thereof will now be described, by way of example only, with reference to the accompanying drawings, of which:

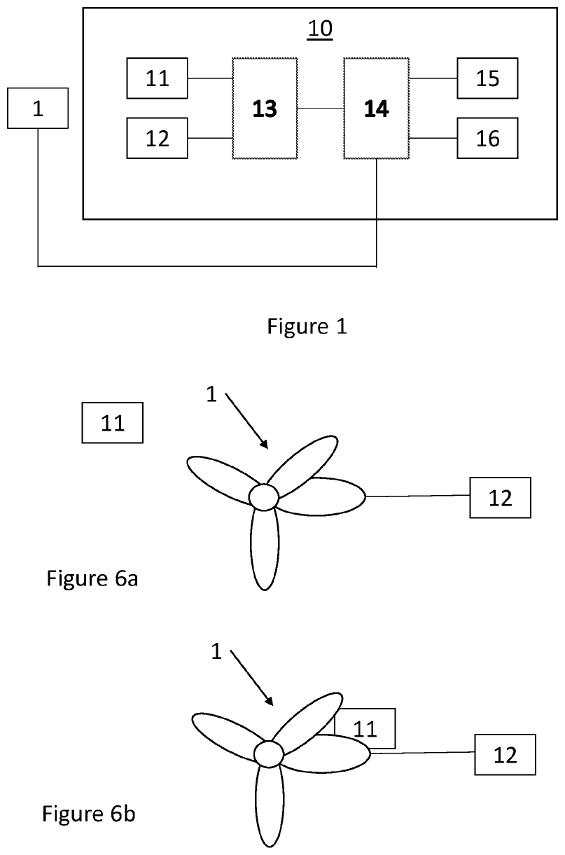

FIG. 1 is a schematic block diagram of an apparatus for monitoring the condition of electrical apparatus according to the present invention;

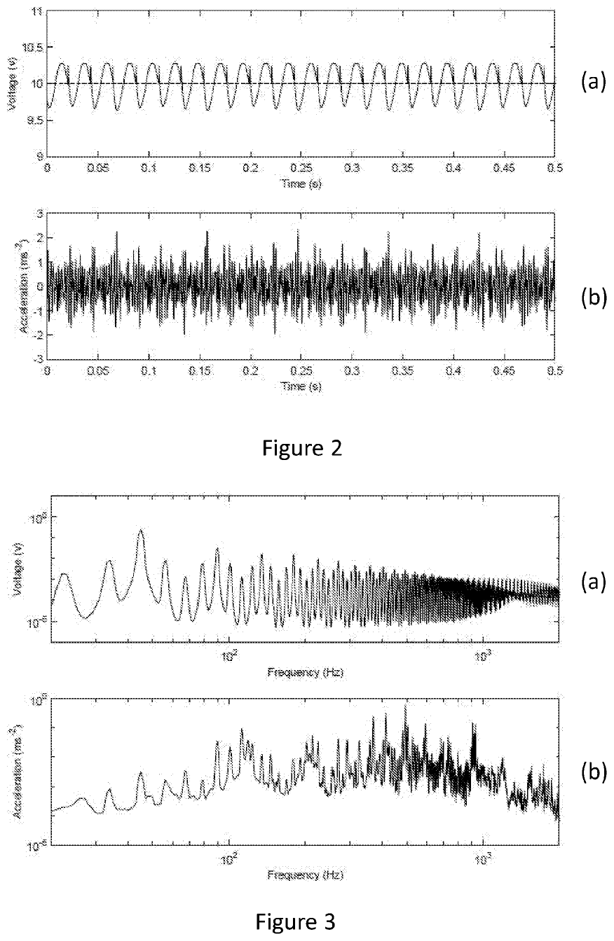

FIG. 2a illustrates a detected characteristic operational electrical signal of a DC electrical motor in operation;

FIG. 2b illustrates a detected vibration signal corresponding to the motor operation in FIG. 2a;

FIG. 3a is a frequency spectrum generated from the detected characteristic operational electrical signal of FIG. 2a;

FIG. 3b is a frequency spectrum generated from the detected vibration signal of FIG. 2b;

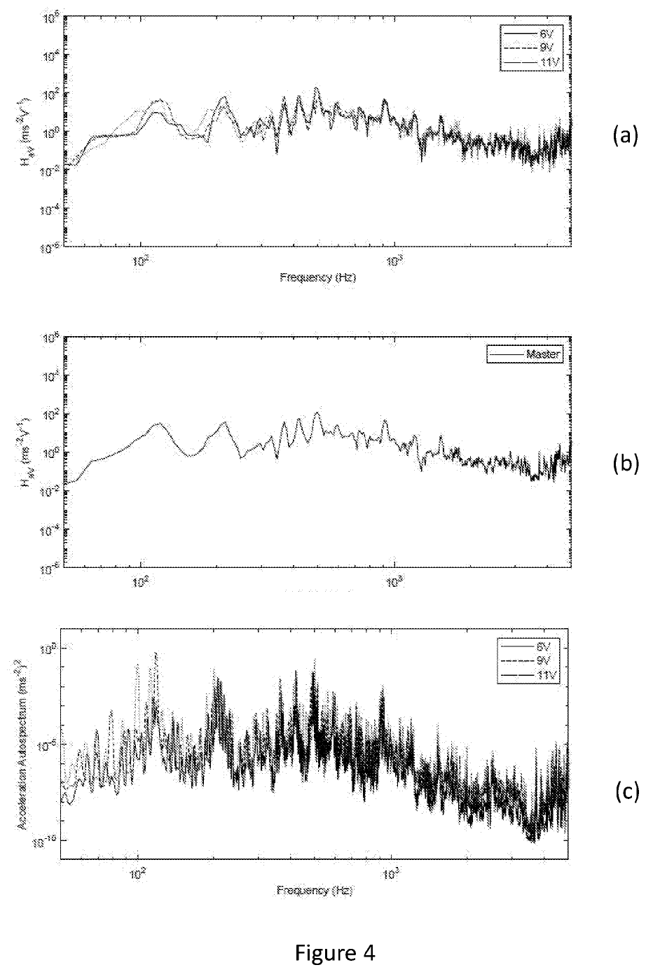

FIG. 4a illustrates acceleration frequency response spectra generated using three different input voltage levels;

FIG. 4b illustrates a model acceleration frequency response function generated by combining the frequency response spectra of FIG. 4a;

FIG. 4c illustrates an acceleration autospectrum as used for analysis in prior art techniques;

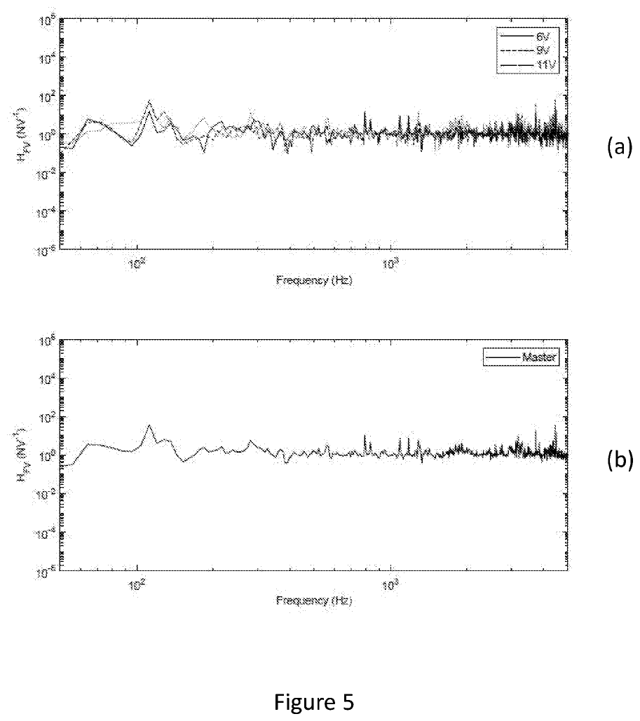

FIG. 5a illustrates blocked force frequency response spectra determined from the corresponding acceleration frequency response spectra of FIG. 4a;

FIG. 5b illustrates a model blocked force frequency response function generated by combining the frequency response spectra of FIG. 5a;

FIG. 6 shows two alternative implementations of the invention in respect of monitoring the condition of a fan;

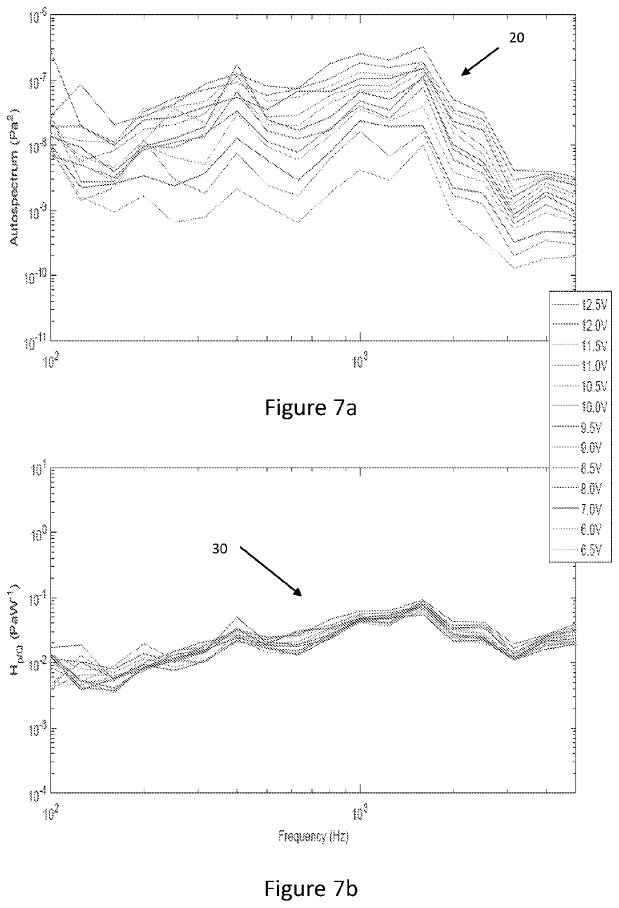

FIG. 7a illustrates vibration frequency spectrums generated in the method of the present invention in respect of the fan of FIG. 6a;

FIG. 7b illustrates frequency response functions generated in the method of the present invention in respect of the fan of FIG. 6a;

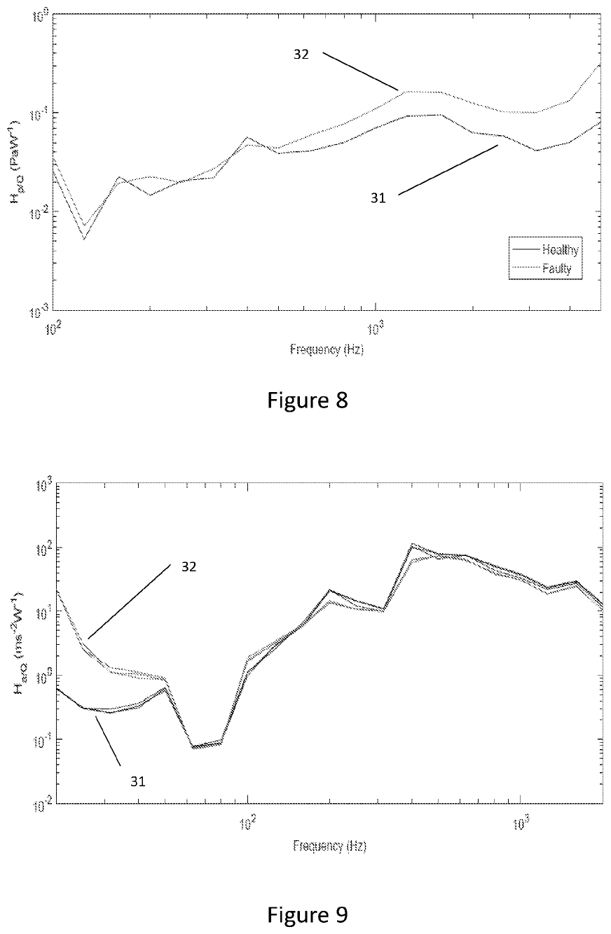

FIG. 8 illustrates a comparison between frequency response functions for healthy and faulty fans of FIG. 6a; and

FIG. 9 illustrates a comparison between frequency response functions for healthy and faulty fans of FIG. 6b.

Turning now to FIG. 1 there is shown an apparatus 10 for monitoring the condition of an item of electrical equipment 1 whilst in operation. Typically, the electrical equipment 1 is a motor, generator or the like and the electrical equipment 1 is typically connected to one or more mechanical components.

The apparatus 10 comprises a vibration sensor 11. Depending on the circumstances, the vibration sensor 11 can comprise an accelerometer, piezoelectric sensor, pressure sensor, Hall effect sensor, microphone, optical fibre grating, strain gauge or the like. The vibration sensor 11 is operable to detect vibration of the equipment 1 during use and output a signal indicative thereof. Whilst the example of FIG. 1 shows a single vibration sensor 11, the skilled man will appreciate that multiple vibration sensors 11 can be provided if necessary.

The apparatus 10 also comprises an electrical sensor 12. The electrical sensor is operable to detect a characteristic operational electrical signal of the equipment 1. The characteristic operational electrical signal might be an input signal for power consuming equipment such as a motor and an output signal for a generator. The electrical sensor 12 can be operable to detect a single attribute of the characteristic operational electrical signal (voltage, current, power) or multiple attributes. As such, the electrical sensor 12 may comprise a voltmeter, ammeter or power meter as required. Whilst the simple example of FIG. 1 shows a single electrical sensor 12, the skilled man will appreciate that multiple electrical sensors 12 can be provided if necessary.

Turning now to FIG. 2, illustrative examples of both a detected characteristic operational electrical signal (FIG. 2a) and a detected vibration signal (FIG. 2b) are shown. The characteristic operation electrical signal is the electrical input signal for a DC motor operating at a constant speed. Whilst the DC motor may be set to operate at a particular voltage input (such as 10V illustrated in FIG. 2a), variation in coil position and brush operation during operation generates a measurable ripple on the base level of the input DC signal, with a period inversely related to the operation speed of the motor. The corresponding vibration signal resulting from operation of the electric motor according to the operating conditions of FIG. 2a is illustrated at FIG. 2b. The output of the vibration sensor 11 and the electrical sensor 12 is supplied to a spectrum generator 13. The spectrum generator 13 is operable to generate a frequency spectrum of the detected vibration and a frequency spectrum of the detected characteristic operational electrical signal. Whilst the example in FIG. 1 shows a single spectrum generator 13, in alternative embodiments, dedicated spectrum generators 13 may be provided for each sensor 11, 12. Turning now to FIGS. 3a and 3b, illustrations of frequency spectra generated from the time domain signals of FIGS. 2a and 2b respectively are shown. Peaks at the operational frequency of the motor (and harmonics of the operational frequency can be observed in the respective frequency spectra.

The output of the spectrum generator 13 is passed to a processing unit 14. The processing unit 14 is operable to process the respective frequency spectrums to generate a frequency response function. The processing unit 14 can generate the frequency response spectrums by use of a multichannel FFT (fast Fourier transform) to generate auto spectrums and cross spectrums as required or by direct calculation from the complex Fourier spectra from which the auto and cross spectra are derived.

Once a frequency response function is generated, the processing unit 14 is operable to compare the generated frequency response function to a model frequency response function. This allows any variations between the generated frequency response function and the model frequency response function to be identified. The occurrence of such variations provides an indication that the equipment 1 is not functioning according to the model frequency response function. This could be indicative of a fault. Indeed, in some instances, the nature of the variation could provide an identification of the nature of the fault.

Additionally, the auto spectrum and cross spectra generated may be used to calculate the coherence of the vibration and characteristic operational electrical signals. Where the coherence is equal to 1, there is a constant relationship between input and output whereas if the coherence drops to less than 1, then the relationship between input and output has changed, which can indicate the development of a fault. Where there are multiple vibration sensors 11 and/or multiple electrical sensors 12, the auto and cross spectra may be additionally utilised for virtual coherence analysis, operational transfer path analysis or principal component analysis.

Where variations from the model frequency response function are identified, the processing unit 14 may provide an output signal indicative of the variations. Optionally, the output signal can result in an indication being output on an output interface 15. The output interface can include means for visual output (such as one or more indicator lamps or a display screen) and means for audio output such as a buzzer, bell, alarm or loudspeaker). Additionally, the output interface may have means for communicating a notification to a remote device or means for printing a local notification. In such embodiments, the output signal may provide details of the nature of the fault (if identified) and/or instructions to perform maintenance.

In some embodiments, where a sufficiently serious fault is identified by comparison of the generated frequency response function to the model frequency response function, the processing unit 14 may be operable to output a command signal to the equipment 1. The command signal may cause operation of the equipment to be shut down. This can forestall potential danger or damage associated with continued operation of faulty equipment.

Optionally, as is shown in FIG. 1, the apparatus may incorporate a data store 16 or be connected to a remote data store 16. The data store can store the model frequency response function. The data store can also maintain a store of generated frequency response functions. This can allow an audit of monitoring activity to take place from time to time. Beneficially, this may help identify early indications of potential future faults.

The model frequency response function can be generated by modelling the expected frequency response of the equipment or by way of a calibration process. In the calibration process, equipment that is understood to be in good operating condition may be operated over the full range of expected operating conditions. During this operation, the vibration sensor 11 and electrical sensor 12 are operable to detect vibration and the characteristic operational electrical signal. The detected signals are processed by the spectrum generator 13 and processing unit 14 to generate frequency response functions. The frequency response functions so generated are stored as model frequency response functions. Where appropriate, a single model frequency response function that describes all operating conditions is generated. Where this is not possible, a series of model frequency response functions may be generated.

This is illustrated in FIG. 4. In FIG. 4a, acceleration frequency response spectra generated using three different input voltage levels are shown. In FIG. 4b, a model frequency response function generated by combining the frequency response spectra of FIG. 4a is illustrated. The skilled man will understand that in practice frequency response spectra from more different input signals may be utilised, as required or as desired.

FIG. 4c shows the acceleration autospectrum from which the acceleration frequency response function and master curve of FIG. 4a and FIG. 4b are derived. The autospectrum of FIG. 4c is what might be analysed in a conventional monitoring technique. As can readily be seen from comparison of the elements of FIG. 4, the present invention both reduces the dynamic range and simplifies the spectrum structure compared to conventional techniques. This can improve the accuracy and ease of fault identification.

Where the calibration process is used, the calibration can be undertaken at the completion of manufacture or installation of the equipment. In some cases, the calibration process can be repeated periodically, for instance after planned servicing. This can enable evolution in the frequency response of the equipment 1 due to use to be taken into account in monitoring.

In some embodiments, the calibration can also involve measuring the accelerance A of the equipment which is essentially the structural frequency response function describing the acceleration of a structure due to a unit force input. Where the accelerance A is known, and the vibration sensor 11 measures acceleration, the present invention can be used to determine the blocked force f_{bl} at the location of vibration sensor 11. The blocked force f_{bl} may be calculated from

f_{bl}=A⁻¹\dot{a}

where \dot{a} is the acceleration at the measurement point and F is a unit force input. As such, the accelerance A can be used to remove the influence of resonances from the model frequency response function. This is illustrated in FIG. 5, where blocked force frequency response functions were determined from the corresponding acceleration frequency response functions of FIG. 4. The resultant functions of FIG. 5a generated from the different input signals and the resultant model function of FIG. 5b are simplified by the removal of structural resonances. This can thereby make it easier to identify faults in general and/or to classify identified faults.

In one specific example of the implementation of the invention, as illustrated schematically in FIG. 6a, the equipment 1 comprises a rotary fan driven by an electric motor and the vibration sensor 11 comprises a sound pressure sensor spaced at 1 m from the fan 1 in a semi anechoic room. FIG. 7a shows a series of one-third octave band frequency spectrums 20 generated by the spectrum generator 13 for vibration detected by sound pressure sensor 11 for a healthy fan 1 running at different speeds determined by the identified DC input voltages. The sound pressure level measured varies widely demonstrating that a broad range of sound pressure levels are observable for healthy items of electrical equipment.

In the present invention, the spectrum generator 13 is also operable to generate a frequency spectrum of the electrical power supplied to fan 1 using an electrical sensor 12 connected to the input power supply. The processing unit 14 is then operable to generate both auto spectra and cross spectra of the detected vibration with respect to input voltage, current or power supplied to the fan 1. The auto and cross spectra are then used to determine frequency response functions 30 relating the vibration to the electrical input as shown in FIG. 7b. In this particular example, the electrical sensor 12 has detected electrical power supplied to the fan 1 and the detected electrical power has been used to generate a frequency response functions 30 relating input electrical power to vibration for the same range of input voltages as used in FIG. 3a. As can be seen for a healthy fan there is relatively little variation in the frequency response function 30 over the full operational range of the fan. As such, it is possible to represent healthy operation of the fan 1 using a single model frequency response function. Nevertheless, the skilled man will appreciate that if greater accuracy is required, a set of model frequency response functions may be used instead of a single model frequency response function.

Turning now to FIG. 8, a comparison is shown between the model frequency response function 31 of a healthy fan 1 and the generated frequency response function 32 of a fan 1 with a faulty blade as measured by sound pressure sensor 12. The difference between the two frequency response functions 31, 32 can be clearly identified by the increase in the magnitude of the generated frequency response function 32 in the frequency range 600-5000 Hz. As a result of identification of this difference: a warning alarm may be output, a maintenance notification generated and/or operation of the fan can be shutdown as required.

To better identify faults or to more accurately detect particular faults, it may be necessary to use different types of vibration sensor 11 or mount vibration sensors 11 at different points on or near the equipment 1. For example, as shown in FIG. 2b, the vibration sensor 11 could comprise an accelerometer fitted to the housing of an equivalent fan to that of FIG. 6a. Once again, a model frequency response function 31 can be generated for the fan 1. In the case that the fan of FIG. 6b has an imbalance fault, the model and generated frequency response functions 31, 32 related to the accelerometer output are shown in FIG. 9. The fault condition can be identified in this case by an increase in the magnitude of the generated frequency response function 32 in the frequency range 20-60 Hz.

The skilled man will therefore appreciate that the particular type, placement and number of vibration sensors 11 (and electrical sensors 12) will be determined by the nature of the equipment and the nature of the expected faults.

The above embodiment is described by way of example only. Many variations are possible without departing from the scope of the invention as defined in the appended claims.

1. A method for monitoring the condition of electrical equipment, the method comprising the steps of: detecting vibration of the equipment; obtaining a frequency spectrum of the detected vibration; detecting a characteristic operational electrical signal of the equipment; obtaining a frequency spectrum of the detected characteristic operational electrical signal; processing the respective frequency spectrums to generate a frequency response function and comparing the generated frequency response function to a model frequency response function so as to identify any variations between the generated frequency response function and the model frequency response function.

2. A method as claimed in claim 1 wherein the method involves detection of more than one characteristic operational electrical signal.

3. A method as claimed in claim 1 wherein more than one attribute of the characteristic operational electrical signal is measured, and the method includes generation of separate frequency response functions for each attribute and comparison of the separate generated frequency response functions for these attributes.

4. A method as claimed in claim 1 wherein the method involves detection of vibration of the equipment at multiple points.

5. A method as claimed in claim 1 wherein the method includes generating separate frequency response functions for each vibration sensor.

6. A method as claimed in claim 1 wherein the method includes the step of calculating the auto spectrum of detected vibration and characteristic operational electrical signals and the cross spectrum of detected vibration and characteristic operational electrical signals.

7. A method as claimed in claim 6 wherein the method includes the step of monitoring the calculated auto and cross spectra over time.

8. A method as claimed in claim 6 wherein the monitoring of the calculated auto and cross spectra involves any one or more of: calculating frequency response functions, coherence; transmissibility (operational transfer path analysis); or principal component analysis.

9. A method as claimed in claim 1 wherein the method includes: generating a force frequency response function from the vibration frequency response function; and comparing the determined force generated frequency response function to a model force frequency response function.

10. A method as claimed in claim 9 wherein determination of the force frequency response function from the measured vibration frequency response function is achieved by inverse methods.

11. A method as claimed in claim 1 wherein the method includes classifying the operation of the equipment in response to any identified variations between the generated frequency response function and the model frequency response function or any identified variations in the calculated auto and/or cross spectra.

12. A method as claimed in claim 8 wherein the method includes the analysis of any identified variations to determine whether a fault has occurred and/or the identity of the fault.

13. A method as claimed in claim 12 wherein the method includes the further step of outputting a signal indicative of the fault; generating a maintenance notification including an indication of the identified fault; or outputting a command signal to shut down all or part of the equipment.

14. A method as claimed in claim 1 wherein the model frequency response function is generated by modelling the expected frequency response of the equipment.

15. A method as claimed in claim 1 wherein the model frequency response function is generated by way of a calibration process.

16. A method as claimed in claim 15 wherein the calibration process is carried out at the completion of manufacture of the equipment; on installation of the equipment; periodically or after servicing.

17. A method as claimed in claim 1 wherein the method includes converting signals from the frequency domain to the time domain for analysis.

18. A method as claimed in claim 1 wherein the method includes monitoring multiple items of electrical equipment.

19. A method as claimed in claim 1 wherein the method includes monitoring machinery linked to electrical equipment.

20. An apparatus for monitoring the condition of electrical equipment, the apparatus comprising: a vibration sensor operable to detect vibration of the equipment and output a signal indicative thereof; an electrical sensor operable to detect a characteristic operational electrical signal of the equipment and to output a signal indicative thereof; a spectrum generator operable to receive the output of the vibration sensor and electrical input sensor and to thereby generate a frequency spectrum of the detected vibration and a frequency spectrum of the detected characteristic operational electrical signal; and a processing unit operable to process the respective frequency spectrums to generate a frequency response function and to compare the generated frequency response function to a model frequency response function so as to identify any variations between the generated frequency response function and the model frequency response function and output an indication thereof.

21. An apparatus as claimed in claim 20 wherein there are multiple characteristic operational electrical signal sensors.

22. An apparatus as claimed in claim 20 wherein the electrical signal sensors are operable to detect any attribute of the characteristic operational electrical signal.

23. An apparatus as claimed in claim 20 wherein there are multiple vibration sensors.

24. An apparatus as claimed in claim 20 wherein the spectrum generator is operable to calculate the auto spectrum of detected vibration and characteristic operational electrical signals and the cross spectrum of detected vibration and characteristic operational electrical signals.

25. An apparatus as claimed in claim 24 wherein the processing unit is operable to monitor the calculated auto and cross spectra over time.

26. An apparatus as claimed in claim 20 wherein the apparatus is operable to generate a force frequency response function from the vibration frequency response function; and compare the generated force frequency response function to a model force frequency response function.

27. An item of electrical equipment monitored according to the method of claim 1.

28. A system comprising a plurality of items of electrical equipment according to claim 27.

29. An item of electrical equipment comprising an apparatus according to claim 20.

30. A system comprising a plurality of items of electrical equipment according to claim 29.
